(19) United States
(12) Patent Application Publication
(10) Pub. No.: US 2013/0014969 A1
(43) Pub. Date: Jan. 17, 2013

(54) STRUCTURE OF CASING OF ELECTRONIC DEVICE

(71) Applicant: CHENG-CHIEN HSU, New Taipei City (TW)

(72) Inventor: CHENG-CHIEN HSU, New Taipei City (TW)

(21) Appl. No.: 13/315,247

(22) Filed: Dec. 8, 2011

(30) Foreign Application Priority Data
Jul. 15, 2011 (TW) 100213047

(51) Int. Cl. H05K 5/00; B32B 37/12; B32B 37/10; B32B 37/02; B32B 37/06

(52) U.S. Cl. 174/50; 156/221

(57) ABSTRACT

The present invention relates to a structure of casing of electronic device, which includes a plurality of flexible wires and a plurality of plastic wires interlacing each other to form a plate. The plate is applied with a bonding agent and is subjected to hot pressing to consolidate and solidify the plate to form a casing having a predetermined shape. In the manufacturing process of the casing, hot pressing is applied to realize multiple times of processing. Further, the plate that is formed of the above described structure can effectively shorten the processing time and is also advantageous in being fireproof and heat resistant.

### TECHNICAL FIELD OF THE INVENTION

The present invention generally relates to a structure of casing of electronic device, and more particularly to a structure of casing of electronic device that is formed of a plate formed by interlacing flexible wires and plastic wires in order to realize processing of multiple times and reduction of processing time.

### DESCRIPTION OF THE PRIOR ART

The modern science and technology bring popular use of computers, smart phones, and related electronic devices. To reduce manufacturing costs, most of the 3C products are provided with a casing that is made by injection molding.

The known injection molding is a process based on epoxy resin, in which various formulas of additives are mixed to realize properly shaping of the casing.

However, such known processes do not allow a secondary processing and this obviously increases the cost of the casing manufacture.

Thus, it is a challenge for the industry to overcome the above discussed problems and drawbacks and is an improvement that the industry must devote themselves to.

### SUMMARY OF THE INVENTION

In view of the above discussed drawbacks, the present invention aims to provide a novel structure of casing of electronic device that is formed of a plate formed by interlacing a plurality of flexible wires and plastic wires to realize processing of multiple times and reduction of processing time.

The primary objective of the present invention is to use a plurality of flexible wires and a plurality of plastic wires that arranged to interlace each other to form a plate in order to shorten processing time and at the same time provides advantages of being fireproof and heat resistant.

To achieve the above objective, the present invention provides a structure of casing of electronic device, which is formed of a plate that is made by interlacing a plurality of flexible wires (such as carbon fibers, nonwoven fabrics, or metal wires) and a plurality of plastic wires (such as polyethylene terephthalate (PET), high density polyethylene (HDPE), polyvinylchloride (PVC), low density polyethylene (LDPE), polypropylene (PP), polycarbonate (PC), or acrylonitrile-butadiene-styrene (ABS)), wherein the plate is combined with a bonding agent and is subjected to hot pressing to solidify the plate for forming a casing of a predetermined shape, and during the process of forming the casing, processing of multiple times is realized by means of hot pressing.

Another objective of the present invention is that the strength of the plate according to the present invention can be varied with change of ratios.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a perspective view showing a preferred embodiment according to the present invention.

FIG. 2 is a partial enlarged view of the preferred embodiment according to the present invention.

FIG. 3 is a schematic view showing an application of the preferred embodiment of the present invention.

FIG. 4 is a perspective view showing another preferred embodiment according to the present invention.

FIG. 4A is another perspective view showing said another preferred embodiment according to the present invention.

FIG. 5 is a schematic view showing an application of said another preferred embodiment of the present invention.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

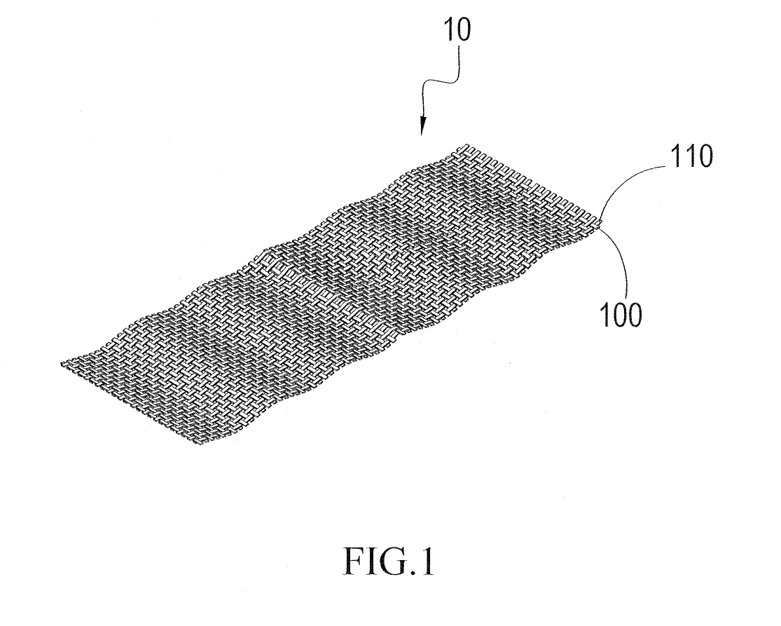

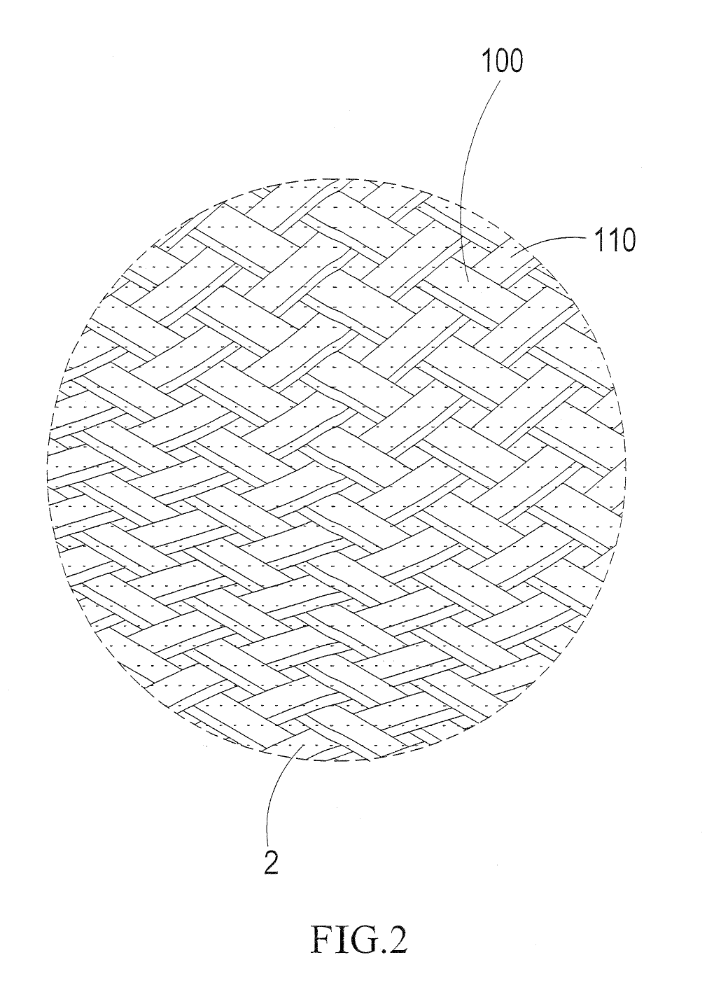

Referring to FIGS. 1 and 2, which are respectively a perspective view and a partial enlarged view of a preferred embodiment of the present invention, the drawings clearly show that a structure of casing of electronic device according to the present invention comprises generally the following constituent components:

A plate 10 is made by interlacing a plurality of flexible wires 100 (such as carbon fibers, nonwoven fabrics, or metal wires) and a plurality of plastic wires 110 (such as polyethylene terephthalate (PET), high density polyethylene (HDPE), polyvinylchloride (PVC), low density polyethylene (LDPE), polypropylene (PP), polycarbonate (PC), or acrylonitrile-butadiene-styrene (ABS)), and the plate 10 is applied with a bonding agent 2 and is subjected to hot pressing to consolidate and solidify the plate 10 for forming a casing 1 having a predetermined shape. The hot pressing of the plate 10 is applied in combination with a vacuum condition in order to achieve the predetermined shape, in which the plate may be further subjected to secondary processing and shaping.

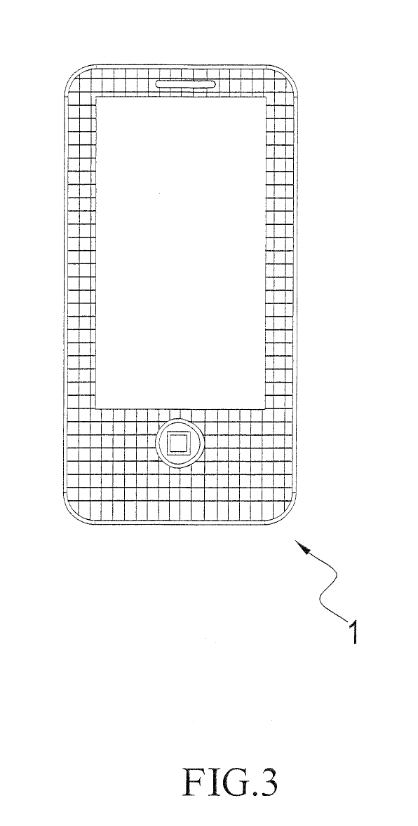

With the above described structure and arrangement, the operation of the present invention will be described as follows, with reference to FIGS. 1, 2, and 3, which are respectively a perspective view and a partial enlarged view of the preferred embodiment of the present invention and a schematic view showing an application of the present invention. These drawings clearly show that the plate 10 is formed by interlacing a plurality of flexible wires 100 and a plurality of plastic wires 110. Examples of the flexible wires 110 and the plastic wires 110 are carbon fibers and polycarbonate (PC), respectively, for the description. When the carbon fibers and the polycarbonate are arranged to interlace with each other to form the plate 10, the plasticity of the plastic wires 110 allows the plate 10, after being subjected to primary shaping, to be further subjected to secondary shaping. The strength of the plate 10 varies with the ratio of the plastic wires 110 and various manufacturing factors. A bonding agent 2 is then applied to the plate 10 and hot pressing is subsequently carried out to consolidate and solidify the plate 10 to show a predetermined shape for forming a casing 1. The casing 1 so completed is applicable to a tablet computer to make it possible for the tablet computer having a casing 1 that is not just made of regular epoxy resin. In this way, the casing 1 so made shows certain practical advantages of being fireproof and heat resistant.

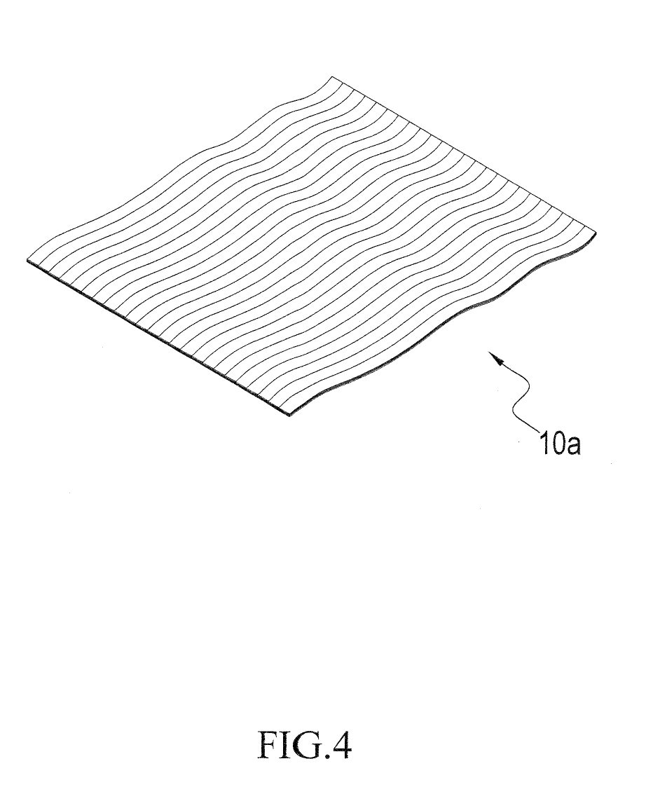

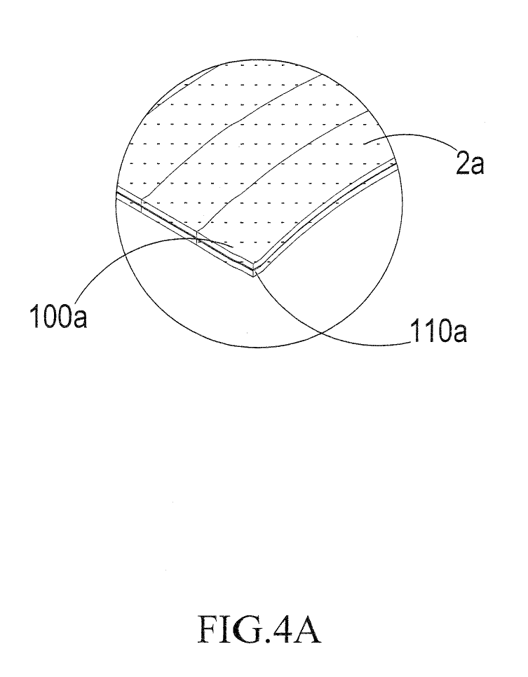

Referring to FIG. 4, which is a perspective view showing another preferred embodiment of the present invention, the drawing clearly shows that a structure of casing of electronic device according to the present invention comprises generally the following constituent components:

A plate 10a is made by alternately stacking a plurality of flexible wires 100a (such as carbon fibers, nonwoven fabrics, or metal wires) and a plurality of plastic wires 110a (such as polyethylene terephthalate (PET), high density polyethylene (HDPE), polyvinylchloride (PVC), low density polyethylene (LDPE), polypropylene (PP), polycarbonate (PC), or acrylonitrile-butadiene-styrene (ABS)), and the plate 10a is applied with a bonding agent 2a and is subjected to hot pressing to solidify the plate 10a for forming a casing 1a having a predetermined shape. The hot pressing of the plate 10a is applied in combination with a vacuum condition in order to achieve the predetermined shape, in which each of the flexible wires 100a has an upper surface that is covered by the plastic wires 110a, or each of the plastic wires 110a has an upper surface covered by the flexible wires 100a, wherein the plate may be further subjected to secondary processing and shaping.

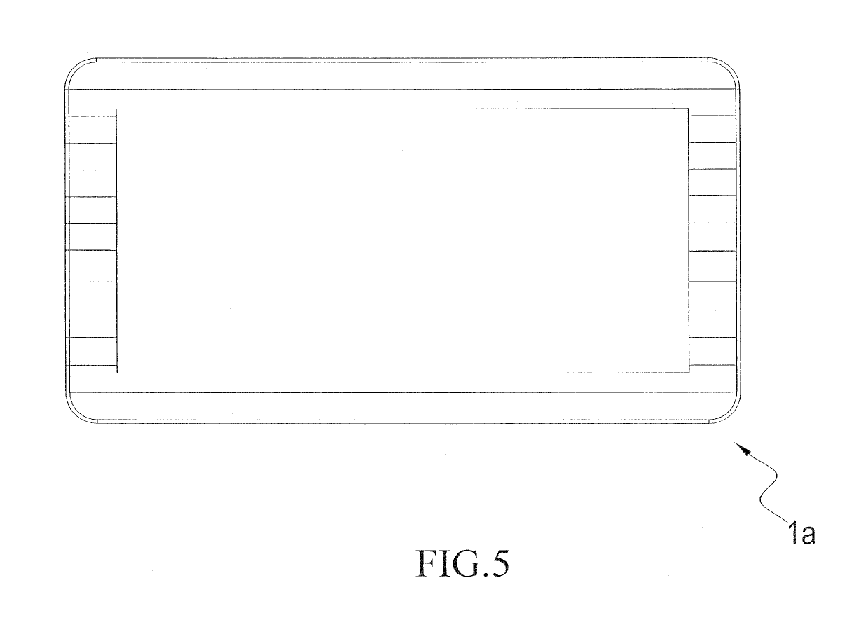

Referring to FIGS. 4, 4A, and 5, which are respectively a perspective view and another perspective view of said another preferred embodiment of the present invention and a schematic view showing an application of the present invention. These drawings clearly show that the plate 10a is formed by alternately stacking a plurality of flexible wires 100a and a plurality of plastic wires 110a. Examples of the flexible wires 110a and the plastic wires 110a are carbon fibers and polycarbonate (PC), respectively, for the description. When the carbon fibers and the polycarbonate are arranged to interlace with each other to form the plate 10a, the plasticity of the plastic wires 110a allows the plate 10a to be selectively and/or additionally subjected to secondary shaping, and the processing time is shortened from 40 minutes that are originally required to only 4 minutes. Further, the strength of the plate 10a varies with the ratio of the plastic wires 110a. A bonding agent 2 is then applied to the plate 10a and hot pressing is subsequently carried out to consolidate and solidify the plate 10a to show a predetermined shape for forming a casing 1a. The casing 1a so completed is applicable to a tablet computer to make it possible for the tablet computer having a casing 1a that is not just made of regular epoxy resin. In this way, the casing 1a so made shows certain practical advantages of being fireproof and heat resistant.

The description given above is provided with reference to preferred embodiments of the present invention and is not intended to impose undue limitations to the scope of the appended claims of the present invention.

Thus, modification and variation of equivalent structure based on the disclosure made in this specification, as well as the attached drawings, all belong to the protection scope of the appended claims.

In summary, with reference to all the drawings, compared to the conventional devices, the present invention, when put into practice, shows the following advantages:

(1) The plate 10 that is formed by interlacing a plurality of flexible wires 100 and a plurality of plastic wires 110 can achieve the advantages of being fireproof and heat resistant.

(2) The present invention allows the structural strength to be varied by varying the ratio of the plastic wires 110.

(3) The processing time that was originally 40 minutes can be shortened to 4 minutes through application of the plastic wires 110 and also, secondary shaping is made possible.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A structure of casing of electronic device comprising: a plurality of flexible wires and a plurality of plastic wires interlacing each other to form a plate, the plate being applied with a bonding agent and being subjected to hot pressing to solidify the plate to form a casing having a predetermined shape.

2. The structure of casing of electronic device according to claim 1, wherein the plastic wires are any one of polyethylene terephthalate (PET), high density polyethylene (HDPE), polyvinylchloride (PVC), low density polyethylene (LDPE), polypropylene (PP), polycarbonate (PC), and acrylonitrile-butadiene-styrene (ABS).

3. The structure of casing of electronic device according to claim 1, wherein the plate is processable for secondary shaping.

4. The structure of casing of electronic device according to claim 1, wherein the flexible wires are any one of carbon fibers, nonwoven fabrics, and metal wires.

5. The structure of casing of electronic device according to claim 1, wherein hot pressing of the plate is applied in combination with a vacuum condition to form the predetermined shape.

6. A structure of casing of electronic device comprising: a plurality of flexible wires and a plurality of plastic wires alternately stacked on each other to form a plate, the plate being applied with a bonding agent and being subjected to hot pressing to solidify the plate to form a casing having a predetermined shape.

7. The structure of casing of electronic device according to claim 6, wherein the plastic wires are any one of polyethylene terephthalate (PET), high density polyethylene (HDPE), polyvinylchloride (PVC), low density polyethylene (LDPE), polypropylene (PP), polycarbonate (PC), and acrylonitrile-butadiene-styrene (ABS).

8. The structure of casing of electronic device according to claim 6, wherein the plate is processable for secondary shaping.

9. The structure of casing of electronic device according to claim 6, wherein each of the flexible wires has an upper surface that is covered by the plastic wires.

10. The structure of casing of electronic device according to claim 6, wherein each of the plastic wires has an upper surface that is covered by the flexible wires.

11. The structure of casing of electronic device according to claim 6, wherein the flexible wires are any one of carbon fibers, nonwoven fabrics, and metal wires.

12. The structure of casing of electronic device according to claim 6, wherein hot pressing of the plate is applied in combination with a vacuum condition to form the predetermined shape.
